(19) United States
(12) Patent Application Publication
(10) Pub. No.: US 2013/0119542 A1
(43) Pub. Date: May 16, 2013

(54) PACKAGE HAVING STACKED MEMORY DIES WITH SERIALLY CONNECTED BUFFER DIES

(71) Applicant: MOSAID Technologies Incorporated, Ottawa (CA)

(72) Inventor: HakJune OH, Ottawa (CA)

(73) Assignee: MOSAID TECHNOLOGIES INCORPORATED, Ottawa (CA)

(21) Appl. No.: 13/675,163

(22) Filed: Nov. 13, 2012

Related U.S. Application Data
(60) Provisional application No. 61/559,230, filed on Nov. 14, 2011.

(51) Int. Cl. H01L 23/498

(52) U.S. Cl. 257/738; 257/E23.069; 257/777

(57) ABSTRACT

A multi-chip package has a substrate, and a plurality of memory dies stacked on the substrate. A plurality of buffer dies each has an input and an output. The input of a first buffer die is connectable to an external input. The output of a last buffer die of the plurality of buffer dies is connectable to an external output. Each of the remaining inputs and outputs is connected respectively to an output or an input of another of the plurality of buffer dies to form a serial connection between the plurality of buffer dies. Each of the memory dies is connected to one of the buffer dies, such that each buffer die is connected to its respective memory dies in parallel arrangement. A memory device having multiple serially interconnected MCPs and a controller is also described.

### CROSS-REFERENCE TO RELATED APPLICATION AND CLAIM OF PRIORITY

This application claims the benefit of priority to U.S. Provisional Patent Application No. 61/559,230, the contents of which are hereby incorporated herein by reference in their entirety.

### FIELD OF THE INVENTION

The invention relates generally to a semiconductor die stacking arrangement, and more specifically to a three-dimensional Multi-Chip-Package (MCP) or Multi-Die-Stacked-Package (MDSP) having serially interconnected memory buffer dies.

### BACKGROUND

The strong growth in demand for portable consumer electronics is driving the need for high-capacity storage devices. Non-volatile semiconductor memory devices, such as flash memory storage cards, are becoming widely used to meet the ever-growing demands for digital information storage and exchange. Their portability, versatility and rugged design, along with their high reliability, high capacity, and low cost, have made such memory devices ideal for use in a wide variety of electronic devices. These devices include, for example, digital music players, cellular phones, handheld PCs, digital cameras, digital video camcorders, smart phones, car navigation systems and electronic books. Flash memory storage cards come in a number of different configurations, but generally include a semiconductor package housed within a standard sized and shaped enclosure. Standard enclosures include SD (Secure Digital) cards, Compact Flash (CF), Smart Media (SM), Mini SD Cards, Multi-Media-Cards (MMC), xD Cards, Transflash memory cards, and Memory Sticks. The semiconductor package used in such memory devices includes an integrated circuit typically having passive components, one or more memory chips and, in some configurations, a controller chip mounted on and electrically connected to a substrate. Substrates on which the integrated circuit may be formed include printed circuit boards, lead-frames and polyimide tapes. Once formed on the substrate, these integrated circuits are typically encapsulated in a molding compound which protects the integrated circuit and removes heat from the package. Where once memory devices included a plurality of discrete semiconductor packages, each handling different functions, currently a plurality of integrated circuit components may be packaged together to provide a complete electronic system in a single package . For example, multichip modules (“MCM”) typically include a plurality of chips mounted side by side on a substrate and then packaged. Another example is a system-in-a-package (“SiP”), where a plurality of chips may be stacked on a substrate and then packaged. With form factors being fixed for most of the standard memory cards currently in use, there are generally only two ways to increase the memory density within a card: use higher density memory chips, and stack more memory dies in a single package. As the memory card space is limited, stacking more memory chips in a package is getting more difficult and expensive.

Conventional Multi-Die-Stacked-Packages (MDSP) can employ many conventional NAND Flash memory dies in a single package, but the number of dies that can be connected in parallel in a single package are limited by some undesired side effects which can adversely affect the performance of the memory device.

As shown in FIG. 1, a NAND flash memory device has common input and output ports DQ[7:0] (sometimes denoted IO[7:0]) for transferring address information, command information and incoming/outgoing data to and from the NAND Flash memory device. FIG. 1 shows an example of conventional flash memory system using a multi-drop bus topology. All input/output signals and control signals except the chip enable (CE#) signal and the ready/busy (RB#) signal in each flash memory die are connected to the common bus or channel. A host memory controller can access each flash memory die via the common bus, and only one flash memory die can be selected at a time by asserting its corresponding chip enable signal. This type of parallel connection method is called a multi-drop connection (or stub bus).

With the conventional system integration approach using the multi-drop connection, signal integrity can become a serious problem when a large number of devices are connected in parallel on a common bus. This is caused by increased capacitive loading, crosstalk, signal skew, and simultaneous switching noise (SSN) from a large number of signals and devices. For example, a typical 2-die stacked package might have 8 pF of input/output capacitance, whereas a similar 4-die stacked package device might have 13 pF of input/output capacitance and a similar 8-die stacked package device might have 23 pF of input/output capacitance. As a result, increasing the number of dies integrated in a single package degrades overall system performance. In addition, this high capacitive loading per package makes system design more difficult and inefficient when many packages must be connected in parallel to achieve a desired memory capacity, for example in a Solid-State Drive (SSD). In a typical SSD system, it is considered that eight NAND flash dies per channel is the effective limit before capacitive loading unacceptably affects the speed of the SSD system. Therefore, many SSD controllers are providing more channels (e.g. 8 or 16 channels) for high-density SSD applications. However, increasing the number of channels on an SSD controller device requires a larger chip size and a more complex system board design, as well as higher power consumption.

Each semiconductor die is typically interconnected with other components by wire bonding as part of the semiconductor device fabrication process. The bonding wire is typically made gold, aluminum or copper. Wire diameters start at 15 μm and can be up to several hundred micro-meters for high-powered applications. There are two main classes of wire bonding: ball bonding and wedge bonding. Ball bonding usually is restricted to gold and copper wire and usually requires heat. Wedge bonding can use either gold or aluminum wire, with only the gold wire requiring heat. In either type of wire bonding, the wire is attached at both ends using some combination of heat, pressure, and ultrasonic energy to make a weld. Wire bonding is generally considered the most cost-effective and flexible interconnect technology, and is used to assemble the vast majority of semiconductor packages.

Conventional memory dies in an MCP system are often interconnected using a parallel interconnection scheme. This “multi-drop” connection scheme involves interconnecting the memory dies such that address and data information and control signals are coupled to the dies in a parallel fashion using common signal buses. Each memory die may incorporate multiple inputs/outputs to accommodate the parallel transfer of the data and address information as well as control signals to the dies. In order to satisfy the demands for increased memory density and multi-functionality, various 3-Dimensional Package-On-Package (PoP) technologies have recently been developed in semiconductor memory IC industries. A conventional 3-dimensional package-on-package is manufactured as described below. After manufacturing a wafer and separating the wafer into a plurality of individual dies, the die is attached and electrically connected to the substrate, and is encapsulated with a molding resin to produce a package. Then, a package-on-package arrangement is obtained by stacking the packages. These package-on-packages employ a lead frame, or a substrate such as a tape circuit board or a printed circuit board. Various interconnection methods such as wire bonding, tape-automated-bonding, or flip-die bonding, are employed to establish electrical connections between the die and the substrate. However, these package-on-packages are manufactured using complex processes. Moreover, these package-on-packages have much bigger sizes than the standard die, thereby reducing the mounting density on the external apparatus. Further, since the package-on-packages employ many substrates, they cause long signal transmission routes, resulting in signal delay.

Alternatively, 3-Dimensional Stacked-Multi-Die-Packages (MCPs) on wafer-level or die-level have the advantage of simple structures, smaller sizes, and simple manufacturing processes. Further, a multi-die-package at the wafer-level does not suffer from signal delay. Generally, multi-die-packages are classified into two types. One is a multi-die-package formed by stacking different types of dies, thereby achieving multi-functionality. The other is a multi-die-package formed by stacking the same types of dies, thereby expanding the memory capacity. The most common type of memory die stacked in an MCP is NAND Flash memory. NAND Flash memory is a non-volatile memory in widespread use as mass storage for consumer electronics, such as digital cameras and portable digital music players. The density of a presently available NAND Flash memory die can be up to 32 Gbits (=4 GBytes), which is suitable for use in popular USB Flash drives since the size of one die is small. However, recent consumer electronics devices with music and video capabilities have spurred demand for ultra-high capacities to store the large amounts of data, which cannot be met by a single NAND Flash memory die. Therefore, multiple NAND Flash memory dies are combined together into a storage system to effectively increase the available storage capacity. For example, Flash storage densities of 250 GB may be required for such applications. However, there may be undesired side effects if too many dies are connected in parallel inside a single package. One shortcoming associated with utilizing parallel interconnections in the MCP system is that they tend to require a large number of interconnections between the dies in order to transfer information and signals to the dies in parallel. This adds to the complexity of printed circuit boards (PCBs) or substrates that implement these MCP systems. Moreover, the performance of these subsystems tends to be limited by undesirable effects associated with large numbers of interconnections, such as crosstalk. In addition, the number of dies incorporated in these subsystems may be limited due to propagation delay of signals carried by the heavily loaded and long interconnections.

FIG. 2 shows a conventional ball assignment for an 8-die stacked NAND Flash memory device in BGA (Ball-Grid-Array) package form, which has 8 chip-enables and dual channels. It should be understood that other ball assignments are possible. Each NAND Flash die has a dedicated Chip-Enable (CE#) signal, so in total 8 CE# balls are assigned at J5, G9, J6, G8, K5, F9, K6, F8. However, Ready/Busy (RB#) signals are shared by pairs of NAND Flash memory dies to reduce the required number of balls, as shown in FIG. 1.

Two separate channels (Channel_1 & Channel_2) are used for the command/address and data signal groups as shown in FIGS. 1 and 2, because of difficulties in loading each channel to operate at a sufficiently high speed, for example DDR-133. Therefore, the 8-Die-Stacked NAND Flash memory device package has almost double the number of balls of a single NAND die Flash memory or 2- or 4-die stacked NAND Flash memory device package. This causes incompatibility issues between 1-to-4-die stacked NAND Flash memory and 8-die stacked NAND Flash memory, because users of NAND Flash memory devices require different PCB design for their applications such as SSD (Solid-State-Drive) products, thereby also increasing manufacturing costs.

Below is brief description of some signals used in conventional NAND Flash memory.

Command Latch Enable (CLE): the CLE input signal is used to control loading of the operation mode command into the internal command register. The command is latched into the command register from the DQ port on the rising edge of the WE# signal while CLE is High.

Address Latch Enable (ALE): the ALE signal is used to control loading address information into the internal address register. Address information is latched into the address register from the DQ port on the rising edge of the WE# signal while ALE is High.

Chip Enable (CE#): the device goes into a low-power Standby mode when CE# goes High while the device is in Ready state. The CE# signal is ignored when the device is in Busy state (R/B# low), such as during a Program or Erase or Read operation, during which the device will not enter Standby mode even if the CE# input goes High.

Write Enable (WE#): the WE# signal is used to control the acquisition of data from the I/O port.

Read Enable (RE#): the RE signal controls serial data output. Data is available after the falling edge of RE#. The internal column address counter is also incremented (Address=Address+1) on this falling edge.

DQ Ports (DQ 0 to 7): DQ 0 to 7 pins are used to input command, address and data, as well as to output data during read operations. DQ pins float to high-Z state when the NAND die is deselected or when the outputs are disabled.

Write Protect (WP#): the WP# signal is used to protect the device from accidental programming or erasing. The internal voltage regulator (high voltage generator) is reset when WP# is Low. This signal is usually used for protecting the data during the power-on/off sequence when input signals are invalid.

Ready/Busy (RB#): the R/B# signal is an open drain pin, and the output signal is used to indicate the operating condition of the device. The R/B# signal is in Busy state (R/B#=low) during the Program, Erase and Read operations, and returns to Ready state (R/B#=high) after completion of the operation.

A number of attempts have been made to address the problems with the parallel interconnection scheme in memory systems, particularly in NAND Flash memory systems, which require high storage density and high speed sequential data throughput. One of the proposed techniques, described in US Patent Publication Nos. 2007/0076479 and 2007/0109833 the contents of which are incorporated by reference herein in their entirety, provides a technique for coupling devices in a serially interconnected die arrangement that employs fewer and shorter connections than parallel interconnection implementations. This arrangement is promoted by MOSAID Technologies Inc., the assignee of the present application, as HLNAND™ (HyperLink NAND) Flash Memory. Serially interconnecting the memory dies can allow the dies to be operated at higher speeds than parallel interconnected dies, because the overall implementation has fewer and shorter interconnections and is therefore less vulnerable to undesirable effects, such as propagation delay and crosstalk. Moreover, fewer and shorter connections tend to reduce the complexity of the implementation. However, as the demand for higher storage capacity and faster throughput increases, further improvements are required.

Therefore, there is a need to provide a NAND Flash memory device which has a high storage capacity and operates at a high speed.

### SUMMARY

It is an object of the present invention to address one or more of the disadvantages of the prior art.

It is another object of the present invention to provide a multi-chip package having multiple serially-interconnected buffer dies each connected to a plurality of memory dies.

In one aspect, a multi-chip package has a substrate. A plurality of memory dies are stacked on the substrate. A plurality of buffer dies each have an input and an output. The input of a first buffer die of the plurality of buffer dies is connectable to an external input of the multi-chip package. The output of a last buffer die of the plurality of buffer dies is connectable to an external output of the multi-chip package. Each of the remaining inputs and outputs is connected respectively to an output or an input of another of the plurality of buffer dies to form a serial connection between the plurality of buffer dies. Each of the memory dies is connected to one of the buffer dies, such that each buffer die is connected to its respective memory dies in parallel arrangement.

In a further aspect, the plurality of stacked memory dies are arranged in a single stack.

In a further aspect, the buffer dies are stacked on a top memory die of the plurality of memory dies.

In a further aspect, the buffer dies are mounted on the substrate.

In a further aspect, the memory dies and the buffer dies are wire bonded to the substrate.

In a further aspect, eight memory dies are connected to each buffer die.

In a further aspect, the plurality of buffer dies is two buffer dies.

In a further aspect, the plurality of buffer dies is three buffer dies.

In a further aspect, the memory dies and the buffer dies are wire bonded to the substrate.

In a further aspect, the memory dies are flash memory dies.

In a further aspect, the memory dies are NAND flash memory dies.

In a further aspect, the memory dies are DRAM memory dies.

In a further aspect, the memory dies are SRAM memory dies.

In a further aspect, the input of the first buffer die is connectable to the external input via a ball grid array. The output of the last buffer die is connectable to the external output via the ball grid array.

In an additional aspect, a memory device comprises a memory controller. A plurality of multi-chip packages are separately mounted on a common substrate and serially connected to the memory controller.

In a further aspect, each of the multi-chip packages is mounted on the substrate via a ball grid array.

Additional and/or alternative features, aspects, and advantages of embodiments of the present invention will become apparent from the following description, the accompanying drawings, and the appended claims.

### BRIEF DESCRIPTION OF THE DRAWINGS

FIG. 1 is a functional block diagram of an 8-die stacked NAND flash memory device according to a prior art embodiment;

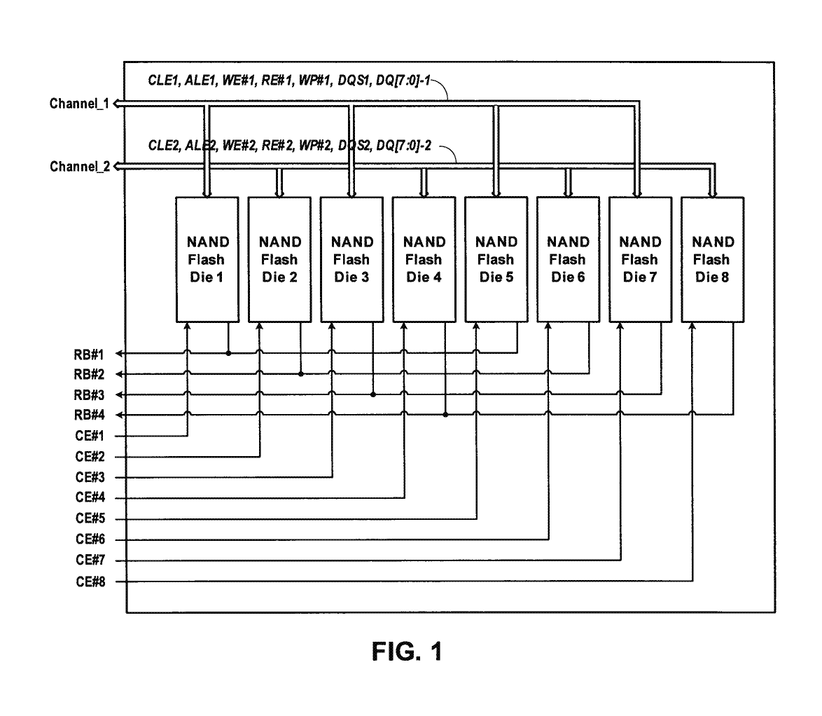

FIG. 2 is a schematic diagram of a ball grid array according to a prior art embodiment that could be used with the memory device of FIG. 1;

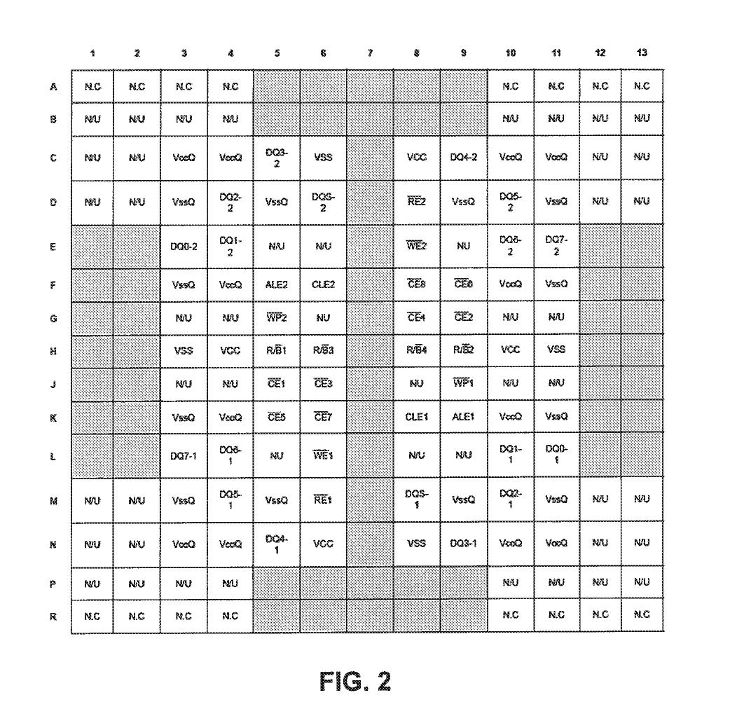

FIG. 3 is a functional block diagram of a multi-die package according to a first embodiment;

FIG. 4 is a schematic diagram of a ball grid array according to a prior art embodiment that could be used with the memory device of FIG. 3;

FIG. 5 is a schematic top plan view of a first wire bonding arrangement of the multi-die package of FIG. 3;

FIG. 6 is a side elevation view of the wire bonding arrangement of FIG. 5;

FIG. 7 is a schematic top plan view of a second wire bonding arrangement of the multi-die package of FIG. 3;

FIG. 8 is a side elevation view of the wire bonding arrangement of FIG. 7;

FIG. 9 is a functional block diagram of a multi-die package according to a second embodiment;

FIG. 10 is a schematic top plan view of a wire bonding arrangement of the multi-die package of FIG. 9; and

FIG. 11 is a schematic diagram of a memory device having multiple multi-die packages.

### DETAILED DESCRIPTION

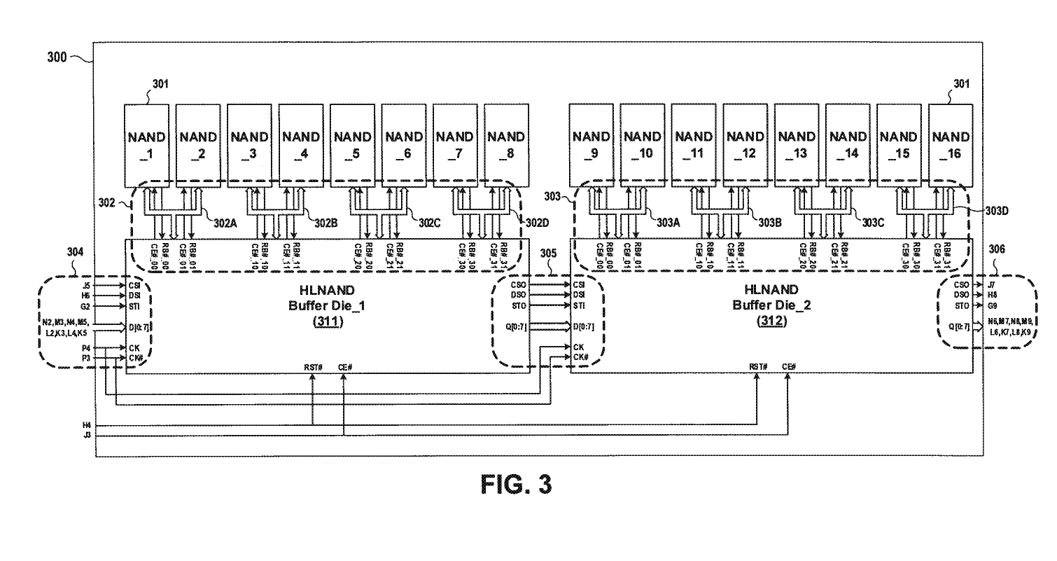

Referring to FIG. 3, an MCP 300 will be described according to a first embodiment. The MCP 300 has two HLNAND buffer dies 311, 312 in series connection and 16 slave memory dies 301 in parallel sub-connection. The HLNAND buffer dies 311, 312 communicate with each other and with external devices via HLNAND Flash interface channels 304, 305, 306. Each HLNAND buffer die 311, 312 communicates with its associated group of eight memory dies 301 via four internal NAND Flash interface channels 302, 303. It should be understood that all of the embodiments described herein are equally applicable to other forms of memory, for example NOR Flash memory, DRAM and SRAM.

The operation of the buffer dies 311, 312 will now be described. Further details of the operation of the buffer dies 311, 312 can be found in US Patent Publication Nos. 2010/0091538 and 2010/0091536, the contents of which are incorporated by reference herein in their entirety. Each HLNAND Buffer die 311, 312 uses a fully multiplexed bus protocol to transfer data, addresses, and commands via the interface channels 304, 305, 306. A link consists of command strobe input/output signals (CSI, CSO), data strobe input/output signals (DSI, DSO), status input/output signals (STI, STO), data signals D[7:0] and Q[7:0], two differential clock input signals CK and CK#, and common signals CE# (Chip Enable Bar) and RST# (Reset Bar). When CSI is logic HIGH, command, address and input-data on D[7:0] are latched on the crossing of CK and CK#. When CSI is logic LOW, the HLNAND Buffer die ignores input signals from D[7:0]. CSI must start on the rising edge of CK. CSO (Command Strobe Output) is an echo signal of CSI and is usually delayed by one clock cycle from the CSI. DSI (Data Strobe Input) enables the Q[7:0] buffers when HIGH. When DSI is LOW, the Q[7:0] buffers hold the previous states. DSI must start on the rising edge of CK. DSO (Data Strobe Output) is an echo signal of DSI and is usually delayed by one clock cycle from the DSI. STO (Status Output) indicates the status of the HLNAND Buffer die operation. When the HLNAND Buffer die operation is completed, STO outputs an asynchronous active high pulse. If multiple HLNAND Buffer dies are serially interconnected as shown in 305 of FIG. 3, the short pulse signal will be bypassed asynchronously through the serial interconnection. STI is a Status Input signal, and it is electrically connected to the STO (Status Output) signal of the previous HLNAND buffer die.

All command, address, input and output data are serially written and read over the link. The HLNAND buffer die is a packet-oriented device. Two types of packets are implemented in the HLNAND buffer die: command and write data packets; and Read data packets. Command and Write data packets contain a command, an optional address, optional write data, and finally, a mandatory EDC byte. Command and write data packets arrive at the HLNAND buffer die through the serial data input port(s), D[7:0], and are delineated by a strobe signal, Command Strobe Input (CSI). Read data packets contain data that is read out of a device heading back to the host controller. Read data packets depart from the HLNAND buffer die through the serial data output port(s), Q[7:0], and are delineated by a strobe signal, DSI (Data Strobe Input). Memory data transfers are specified by a start address and a transfer length. The transfer length is defined by the length of the corresponding strobe signal (CSI or DSI) from its rising edge to its falling edge. All commands, addresses, and data are shifted in and out of the device. Data input (D[7:0]) is sampled at the positive and negative clock edges (i.e., at the crossing point of clocks CK, CK#) while Command Strobe Input (CSI) is HIGH. Each command consists of a one-byte device address (DA), a one-byte OP code, and additional bytes of column address, row address, EDC, or data input as required. Once CSI goes HIGH, the one-byte DA must be shifted in to specify device address followed by a one-byte OP code. Each byte of the commands, addresses, and data are shifted in to the D[7:0] pins and latched on each crossing of CK and CK# while CSI is HIGH. However, each new input sequence must start at a rising edge of CK (=falling edge of CK#). The signal bus on the HLNAND Buffer die is fully multiplexed, so that commands, addresses and data all share the same pin(s). The bus operates at Double Data Rate (DDR) and command, address, and data signals are input and output on every clock edge. The multiplexed command, address, and data signals on the D[7:0] pins are valid and latched into the device when CSI (Command Strobe Input) is in the logic-HIGH state. When CSI and DSI are in the logic LOW state, the device ignores signal inputs on the D[7:0] pins. The command input sequence normally consists of one-byte DA (Device Address), one-byte command, possibly a number of bytes of address (typically 3 bytes for row address or 3 bytes for column address), an EDC byte, and possibly a number of bytes of input data. A one-byte packet is transferred in one half clock cycle.

Referring still to FIG. 3, the first HLNAND Flash interface channel 304 communicates the signals CSI, DSI, STI, D[0:7] and CK/CK# from the BGA (which receives these signals from either another series-connected MCP or a memory controller) to the buffer die 311. In this embodiment, CSI is assigned to external ball J5; DSI is assigned to external ball H6; STI is assigned to external ball G2; D[0:7] are assigned to external balls N2, M3, N4, M5, L2, K3, L4 and K5 respectively; CK is assigned to external ball P4; and CK# is assigned to external ball P3.

The second HLNAND Flash interface channel 305 communicates the signals CSO, DSO, STO and Q[0:7] from the first HLNAND buffer die 311 to the second HLNAND buffer die 312, as CSI, DSI, STI, D[0:7]. The second HLNAND Flash interface channel 305 additionally communicates the signals CK/CK# from the BGA to the second HLNAND buffer die 312. It should be understood that the signals CK/CK# may alternatively be serially communicated from the HLNAND buffer die 311 to the HLNAND buffer die 312 via the HLNAND flash interface channel 305. CSO of the first HLNAND die 311 is interconnected to CSI of the second HLNAND buffer die 312, DSO of the first HLNAND die 311 is interconnected to DSI of the second HLNAND buffer die 312, STO of the first HLNAND die 311 is interconnected to STI of the second HLNAND buffer die 312 and Q[0:7] of the first HLNAND die 311 are interconnected to D[0:7] of the second HLNAND buffer die 312. All of the interconnections between two HLNAND buffer dies (311, 312) can be done by package substrate PCB traces (not shown), either in microstrip or stripline.

The third HLNAND Flash interface channel 306 communicates the signals CSO, DSO, STO, Q[0:7] from the second HLNAND buffer die 312 to the BGA. CSO is assigned to external ball J7; DSO is assigned to external ball H8; STO is assigned to external ball G9; and Q[0:7] are assigned to external balls N6, M7, N8, M9, L6, K7, L8 and K9 respectively. The BGA sends these signals to either another series-connected MCP similar in design to the MCP 300, or a memory controller.

RST# (ball H4) provides a reset for the HLNAND buffer dies. When RST# is HIGH, the HLNAND buffer die is on the normal operating mode. When RST# is LOW, the HLNAND buffer die will enter the hard reset mode. CE# (ball J3) provides a chip enable status. When CE# is LOW, the HLNAND buffer die is enabled. In addition, CE#'s LOW state activates the internal clock signals and CE#'s HIGH state deactivates the internal clock signals. RST# and CE# signals may be commonly connected to both HLNAND buffer dies 311, 312 as shown in FIG. 3.

Referring still to FIG. 3, the first HLNAND Buffer Die 311 communicates with four groups of NAND flash memory dies 301 via four internal NAND flash interface channels 302. Each NAND flash memory die 301 may be a conventional NAND flash memory device. In this embodiment, each group consists of two NAND flash memory dies 301. However, it is contemplated that each group could have only one die 301, or more than two dies 301, and that there could be more or fewer channels 302. In particular, it is contemplated that each HLNAND buffer die 311, 312 might have four associated NAND flash memory dies 301, so that a package according to this embodiment could realize improved performance relative to a conventional 8-die stack having the same storage capacity. The four internal NAND Flash interface channels 302A-302D are evenly allocated to the four groups of NAND flash memory dies 301, NAND_1-NAND_8. The NAND flash interface channel 302A connecting the buffer die 311 to the flash memory dies 301 NAND_1 and NAND_2 will be described, and it should be understood that the remaining NAND flash interface channels 302B, 302C, 302D function in a similar manner, and additionally that the channels associated with the buffer die 312 function in a similar manner. Each NAND flash memory die 301 has common input and output ports (DQ[7:0] or IO[7:0]) for transferring address information, command information and incoming/outgoing data to and from the NAND Flash memory die 301 over the interface 302. All input and output signals and control signals except the chip select (CE#) signal and the ready/busy (RB#) signal in the flash memory dies 301 NAND_1 and NAND_2 are connected to the common bus or channel 302. The HLNAND Buffer die 311 can access one of two NAND flash memory dies 301 (NAND_1 or NAND_2) through the internal NAND flash interface channel 302A, and only one of those two NAND flash memory dies 301 can be selected and be instructed at a time by asserting the corresponding chip enable signals (CE#_00 for NAND_1 or CE#_01 for NAND_2). Similarly, ready/busy signals (RB#_00 for NAND_1 and RB#_01 for NAND_2) can be used to individually monitor the status of each NAND flash memory die 301.

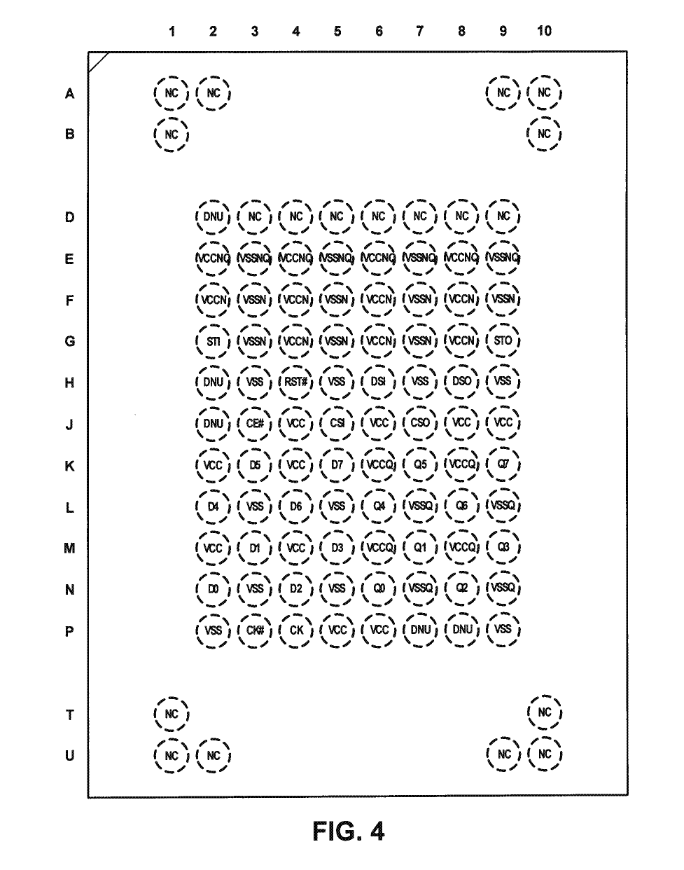

Referring to FIG. 4, a proposed ball assignment will be described for the MCP 300 of FIG. 3. Input signals are allocated on the left side of the package ball array, and output signals are allocated on the right side of the package ball array. For example, input signals CSI, DSI, D0, D1, D2, D3, D4, D5, D6 and D7 are assigned on the balls J5, H6, N2, M3, N4, M5, L2, K3, L4 and K5, respectively. And corresponding output signals CSO, DSO, Q0, Q1, Q2, Q3, Q4, Q5, Q6 and Q7 are assigned on the balls J7, H8, N6, M7, N8, M9, L6, K7, L8 and K9, respectively. With this symmetrical ball assignment, the lengths of traces between the outputs of one package and the inputs of another package can be minimized when two packages are mounted on a common system board, as will be discussed below in further detail. Additional ball assignments are shown for power supplies such as VCC, VCCN, VCCNQ, VSS, VSSN and VSSNQ. Additional balls are assigned as NC (No Connection) and DNU (Do Not Use) are shown. In another embodiment (not shown), clock signals (CK, CK#) can be connected in series by assigning clock output signals CKO & CKO# respectively to balls P7 and P8 when series point-to-point connection is desired.

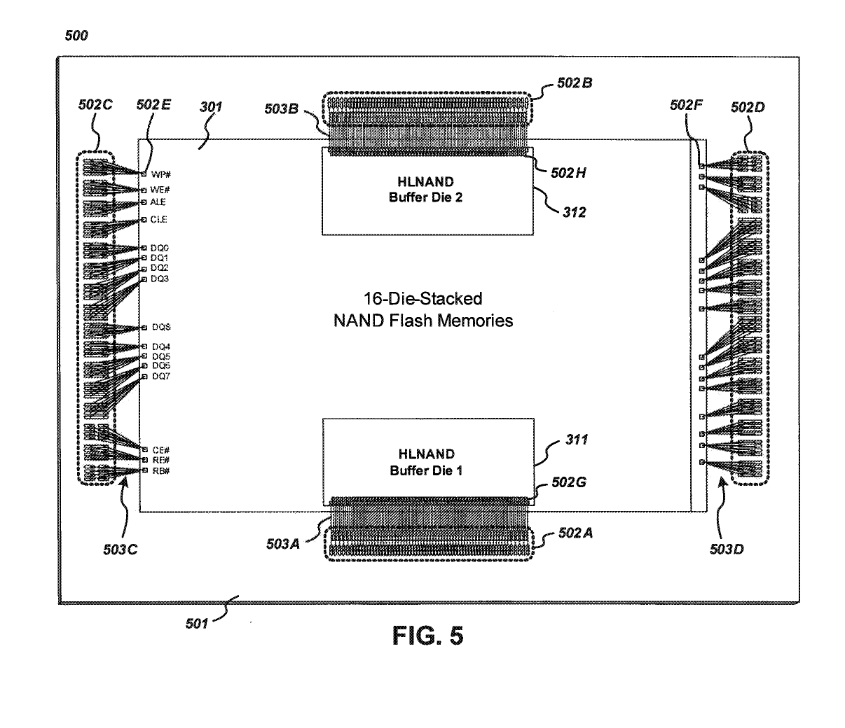

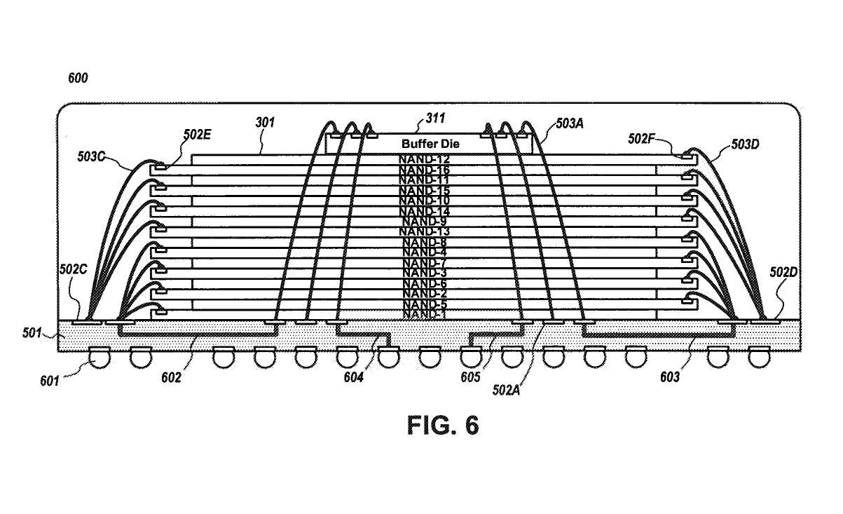

FIGS. 5 and 6 show a first example of how the device of FIG. 3 might be assembled in a package using wire bonding to form an MCP 500. In this arrangement, 16 NAND flash memory dies 301 and two HLNAND buffer dies 311, 312 are stacked on a printed circuit board (PCB) substrate 501. Bonding pads 502E, 502F, 502G, 502H on the dies 301, 311, 312 are bonded to the landing pads 502A, 502B, 502C, 502D on the substrate 501 using bonding wires 503, only some of which are shown, which may be made of any suitable material such as gold or copper. The NAND flash memory dies 301 are shown with bonding pads 502 along only a single edge. However, it is contemplated that other known bonding pad arrangements may alternatively be used, such as arranging the bonding pads 502 along two adjacent edges of each die 301, with the landing pads 502A, 502B, 502C, 502D being arranged accordingly.

Referring to FIG. 6, the substrate 501 has exposed solder ball contacts (601) on its bottom surface, arranged according to the mechanical outline specification of the BGA shown in FIG. 4. The solder balls 601 are interconnected to the corresponding landing pads 502A, 502B (some of which are not shown) on the substrate 501 that are wire bonded to the buffer die 311. Additional landing pads 502A, 502B are connected via traces 602 to corresponding landing pads 502C, 502D that are wire bonded to the NAND flash memory dies 301, to provide communication between the buffer die 311 and the NAND flash memory dies 301. Additional connections (not shown) representing the interface channel 305 between the buffer dies 311 and 312, as well as the interface channels 303 between the buffer die 312 and its corresponding NAND flash memory dies 301 the interface channel 306 between the buffer die 312 and the BGA, are formed by bonding wires 503 and traces in the substrate 501 in a similar manner.

Referring still to FIG. 6, the first NAND flash die NAND_1 is attached to the substrate 501 by any suitable method, for example using an adhesive attach-film or an interposer. The second NAND flash die NAND_5 is then stacked and attached to the top of the die NAND_1 by using a similar adhesive film or interposer, with the die NAND_5 oriented at a 180° angle with respect to the die NAND_1, such that the bonding pads 502 of dies NAND_1 and NAND_5 face in opposite directions. The die NAND_5 is positioned with a slight lateral offset relative to the die NAND_1. This offset position exposes the edge of the die NAND_1 on which the bonding pads 502E are disposed, thereby permitting wire bonding for the die NAND_1. The third die NAND_2 and subsequent odd-numbered dies are positioned directly above the first die NAND_1. The fourth die NAND_6 and subsequent even-numbered dies are positioned directly above the second die NAND_5. It is contemplated that other stacking arrangements for the NAND flash memory dies 301 may alternatively be used, many of which are known in the art. Each die 301 is electrically connected to the appropriate landing pads 502C, 502D on the substrate 501 with bonding wires 503C, 503D.

The stacking order of the NAND flash dies 301 is such that dies sharing common connections, e.g. NAND_1 and NAND_2 which share an interface channel 302, are positioned close to each other in the die stack and oriented with their bonding pads 502E, 502F on the same side of the die stack, thereby simplifying the interconnections and reducing the length of the traces, with a resulting reduction in complexity of the substrate 501. However, it should be understood that alternative stacking arrangements could be used.

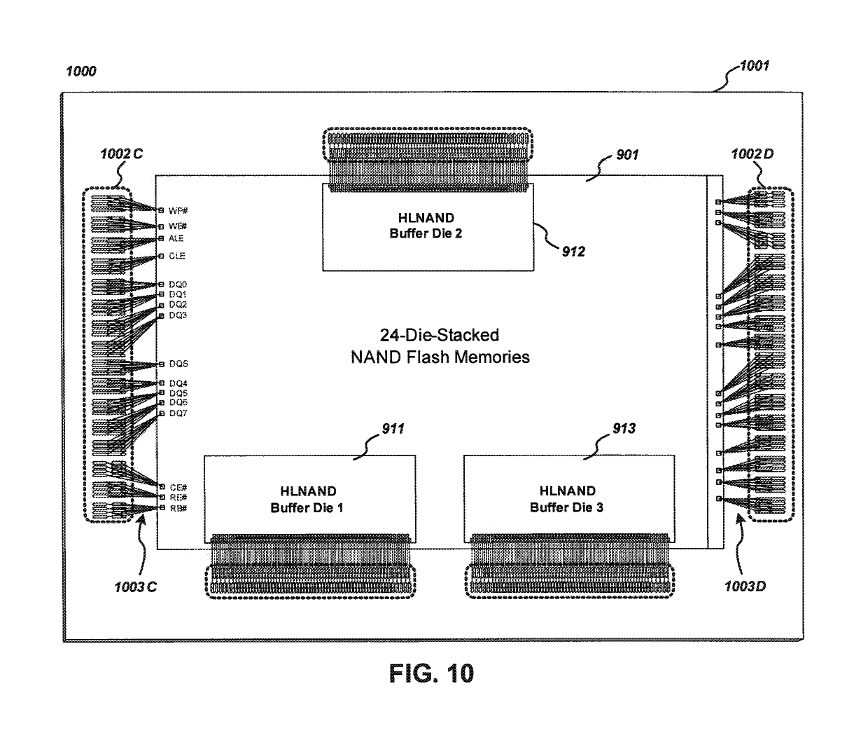

Referring to FIG. 5, in this arrangement the buffer dies 311, 312 are mounted on the top die 301 of the stack of NAND flash memory dies 301. Each of the buffer dies 311, 312 is preferably arranged along an edge of the die stack where the bonding wires 503 are not connected to the dies 301, thereby reducing the congestion between the bonding wires 503C, 503D of the NAND flash memory dies 301 and the bonding wires 503A, 503B of the buffer dies 311, 312. The buffer dies 311, 312 are shown on opposite sides of the top NAND flash memory die 301, but it is contemplated that the buffer dies 311, 312 may alternatively be positioned along the same edge of the top NAND flash memory die 301, similarly to the buffer dies 911, 913 of FIG. 10.

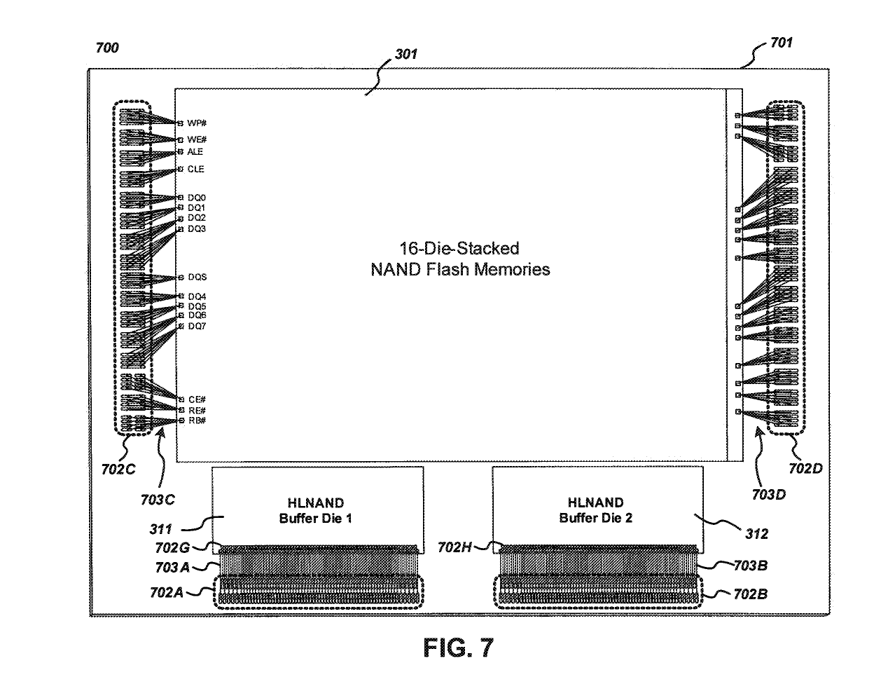

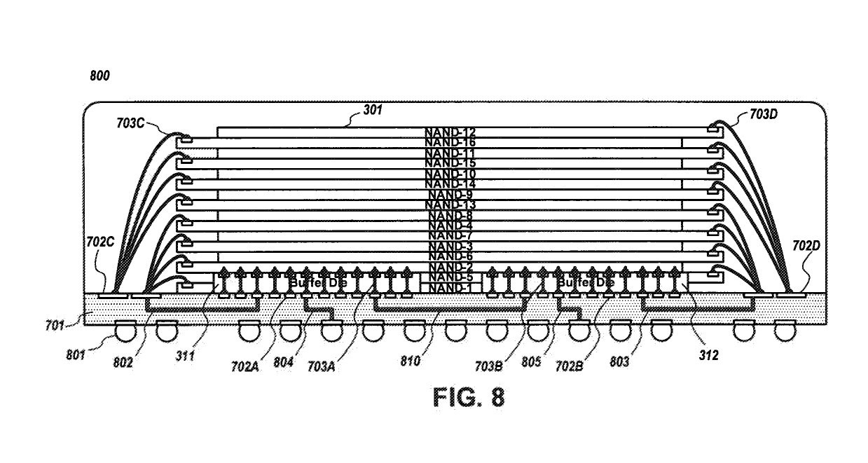

FIGS. 7 and 8 show a second example of how the device of FIG. 3 might be assembled in a package using wire bonding to form an MCP 700. In this arrangement, 16 NAND flash memory dies 301 are stacked on a printed circuit board (PCB) substrate 701 in a similar manner to the arrangement of FIG. 5, and two HLNAND buffer dies 311, 312 are mounted on the substrate 701 alongside the stack of dies. Bonding pads 702E, 702F, 702G, 702H on the dies 301, 311, 312 are bonded to the landing pads 702A, 702B, 702C, 702D on the substrate 701 similarly to the arrangement of FIG. 5. The NAND flash memory dies 301 are shown with bonding pads 702 along only a single edge. However, it is contemplated that other known bonding pad arrangements may alternatively be used, such as arranging the bonding pads 702 along two adjacent edges of each die 301, with the landing pads 702A, 702B, 702C, 702D being arranged accordingly.

Referring to FIG. 8, the substrate 701 has exposed solder ball contacts (801) on its bottom surface, arranged according to the mechanical outline specification of the BGA shown in FIG. 4. The solder balls 801 are interconnected to the corresponding landing pads 702A, 702B (some of which are not shown) on the substrate 701 that are wire bonded to the buffer dies 311, 312. Additional landing pads 702A, 702B are connected via traces 802 to corresponding landing pads 702C, 702D that are wire bonded to the NAND flash memory dies 301, to provide communication between the buffer die 311 and the NAND flash memory dies 301. Additional connections (not shown) representing the interface channel 305 between the buffer dies 311 and 312, as well as the interface channels 303 between the buffer die 312 and its corresponding NAND flash memory dies 301 the interface channel 306 between the buffer die 312 and the BGA, are formed by bonding wires 703 and traces in the substrate 701 in a similar manner.

Referring to FIG. 7, in this arrangement the buffer dies 311, 312 are mounted on the substrate alongside the stack of NAND flash memory dies 301. The buffer dies 311, 312 are shown on the same side of the stack of NAND flash memory dies 301, but it is contemplated that the buffer dies 311, 312 may alternatively be positioned differently, for example on opposite sides of the stack. While this arrangement may require a larger area of usable substrate than the arrangement of FIG. 5, it can provide shorter bonding wires between HLNAND buffer dies (311, 312) and the landing pads (702A, 702B), which may result in better signal quality for the external channels of the HLNAND package.

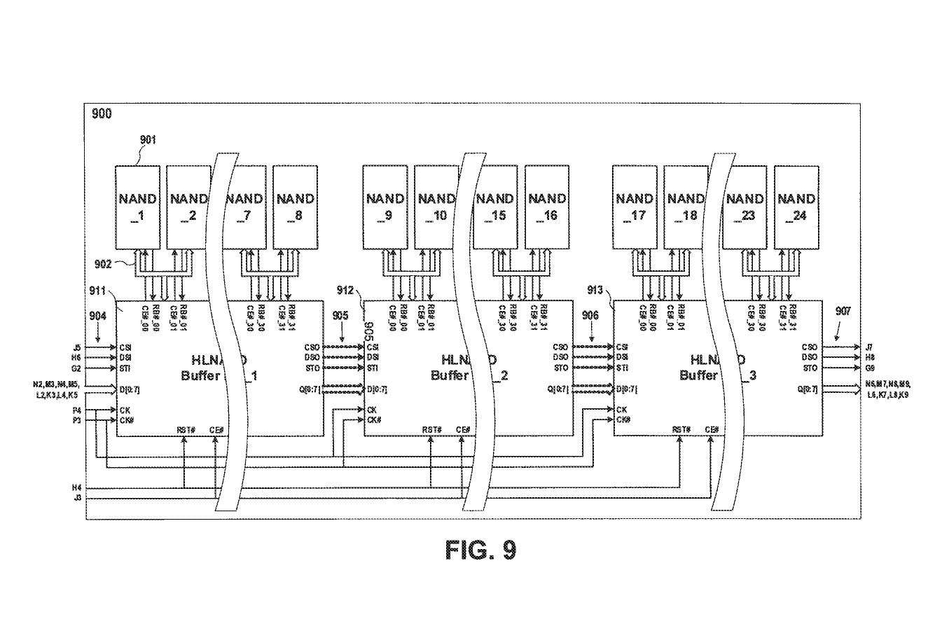

Referring to FIGS. 9 and 10, an MCP 900 will be described according to a second embodiment. The MCP 900 has three HLNAND buffer dies 911, 912, 913 in series connection and 24 slave memory dies 901 in parallel sub-connection. The HLNAND buffer dies 911, 912, 913 communicate with each other and with external devices via HLNAND Flash interface channels 904, 905, 906, 907. Each HLNAND buffer die 911, 912, 913 communicates with its eight associated memory dies 901 via four internal NAND Flash interface channels 902, similarly to the embodiment of FIG. 3. It is contemplated that each HLNAND buffer die 911, 912, 913 could have more or fewer dies, arranged in more or fewer channels 902, similarly to the embodiment of FIG. 3. In particular, it is contemplated that each HLNAND buffer die 911, 912, 913 might have four associated NAND flash memory dies 901, so that a package according to this embodiment could realize improved performance relative to a conventional 8-die stack while having a 50% greater storage capacity.

Referring to FIG. 10, the 24 NAND flash memory dies 901 are stacked on a PCB substrate 1001, and wire bonded to landing pads 1002 on the substrate via bonding wires 1003, similarly to the embodiment of FIG. 5. The three HLNAND buffer dies 911, 912, 913 are mounted on the top die 901 of the stack of NAND flash memory dies 901. Each of the buffer dies 911, 912, 913 is preferably arranged along an edge of the die stack where the bonding wires 1003 are not connected to the dies 901, thereby reducing the congestion between the bonding wires 1003C, 1003D of the NAND flash memory dies 901 and the bonding wires 1003A, 1003B, 1003E of the buffer dies 911, 912, 913. It is contemplated that the buffer dies 911, 912, 913 may alternatively be mounted to the substrate alongside the dies 901, similarly to the arrangement of FIG. 7. This embodiment is similar to the embodiment of FIG. 3, but with the addition of a third HLNAND buffer die 913 connected in series with the HLNAND buffer dies 911, 912 via the channel 906, and eight additional stacked NAND flash memory dies 901 connected to the buffer die 913 in parallel. It should be understood that one or more additional buffer dies could be added in serial connection in a similar manner, which would permit the addition of correspondingly more NAND flash memory dies 901.

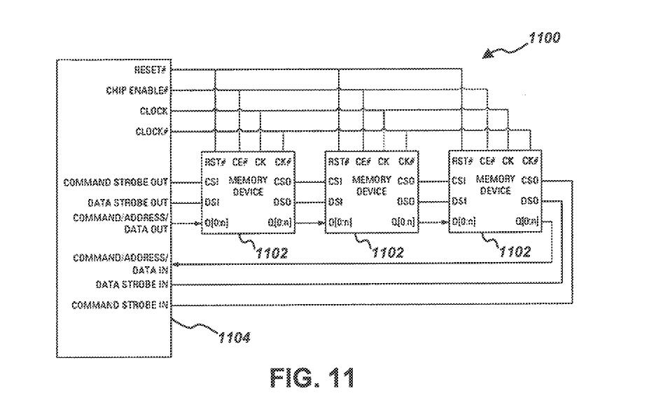

Referring to FIG. 11, a memory device 1100 includes a plurality of MCPs 1102 (three of which are shown) mounted on a common system board via their respective ball grid arrays. Each MCP 1102 may have the same internal configuration as the MCP 300, 500, 700 or 900 described above. The MCPs 1102 are serially interconnected with each other and with a memory controller 1104 through their respective ball grid arrays via traces in the system board. Some signals, such as RST#, CE#, CK and CK# are connected in parallel, however it is contemplated that, for example, the CK, CK# signals may alternatively be connected in series between the MCPs 1102. It is contemplated that any number of memory devices 1102 may be connected in series in this manner, subject to limitations on the dimensions of the system board and the capacity of the controller 1104. This arrangement further increases the available storage capacity by providing multiple MCPs 1102 in a single device, each of which contains multiple NAND flash memory chips connected to one of a plurality of buffer dies.

It should be understood that an HLNAND package as described above can achieve very high storage capacity in a single BGA package without requiring extra balls for the BGA package to account for an increased number of channels. As a result, the ball configuration provides backward compatibility with smaller capacity HLNAND devices which have only a single buffer die. In addition, the ability to stack greater numbers of flash memory dies in a single package reduces by 1/2 to 2/3 the PCB area occupied by the same amount of storage capacity, thereby correspondingly increasing the storage capacity of devices such as SSDs which have predetermined standard dimensions, without unacceptably degrading the signal quality or access speed of the memory device.

Modifications and improvements to the above-described embodiments of the present invention may become apparent to those skilled in the art. The foregoing description is intended to be by way of example rather than limiting. The scope of the present invention is therefore intended to be limited solely by the scope of the appended claims.

1. A multi-chip package, comprising:
a substrate;
a plurality of memory dies stacked on the substrate; and
a plurality of buffer dies each having an input and an output,
the input of a first buffer die of the plurality of buffer dies being connectable to an external input of the multi-chip package;
the output of a last buffer die of the plurality of buffer dies being connectable to an external output of the multi-chip package; and
each of the remaining inputs and outputs being connected respectively to an output or an input of another of the plurality of buffer dies to form a serial connection between the plurality of buffer dies,
each of the memory dies being connected to one of the buffer dies, such that each buffer die is connected to its respective memory dies in parallel arrangement.

2. The multi-chip package of claim 1, wherein:
the plurality of stacked memory dies are arranged in a single stack.

3. The multi-chip package of claim 2, wherein:
the buffer dies are stacked on a top memory die of the plurality of memory dies.

4. The multi-chip package of claim 2, wherein:
the buffer dies are mounted on the substrate.

5. The multi-chip package of claim 1, wherein:
the memory dies and the buffer dies are wire bonded to the substrate.

6. The multi-chip package of claim 1, wherein:
eight memory dies are connected to each buffer die.

7. The multi-chip package of claim 6, wherein:
the plurality of buffer dies is two buffer dies.

8. The multi-chip package of claim 6, wherein:
the plurality of buffer dies is three buffer dies.

9. The multi-chip package of claim 1, wherein:
the memory dies and the buffer dies are wire bonded to the substrate.

10. The multi-chip package of claim 1, wherein:
the memory dies are flash memory dies.

11. The multi-chip package of claim 10, wherein:
the memory dies are NAND flash memory dies.

12. The multi-chip package of claim 1, wherein:
the memory dies are DRAM memory dies.

13. The multi-chip package of claim 1, wherein:
the memory dies are SRAM memory dies.

14. The multi-chip package of claim 1, wherein:
the input of the first buffer die is connectable to the external input via a ball grid array; and
the output of the last buffer die is connectable to the external output via the ball grid array.

15. A memory device, comprising:
a memory controller; and
a plurality of multi-chip packages according to claim 1, the multi-chip packages being separately mounted on a common substrate and serially connected to the memory controller.

16. The memory device of claim 15, wherein:
each of the multi-chip packages is mounted on the substrate via a ball grid array.
